(19) United States
(12) Patent Application Publication
(10) Pub. No.: US 2026/0089980 A1
(43) Pub. Date: Mar. 26, 2026

(54) CAPACITOR STRUCTURE AND METHOD OF FORMING THE SAME

(71) Applicant: NANYA TECHNOLOGY CORPORATION, New Taipei City (TW)

(72) Inventor: Chih-Hsiung HUANG, New Taipei City (TW)

(21) Appl. No.: 18/890,764

(22) Filed: Sep. 20, 2024

(51) Int. Cl. H10D 1/00; H10D 1/68

(52) U.S. Cl. CPC H10D 1/042; H10D 1/716

(57) ABSTRACT

The present disclosure provides a capacitor structure. The capacitor structure includes a bottom electrode, a first dielectric layer, and a first top electrode. The bottom electrode includes a bottom portion and a side portion, in which the side portion extends upward from an edge of the bottom portion, the side portion includes a first portion and a second portion on the first portion, in which a first width of the first portion is smaller than a second width of the second portion. The first dielectric layer is on the bottom electrode. The first top electrode is on the first dielectric layer.

### BACKGROUND

### FIELD OF INVENTION

The present disclosure relates to a capacitor structure and a method of forming the same.

### DESCRIPTION OF RELATED ART

Capacitors are widely used in semiconductor devices, for example, in dynamic random-access memories (DRAMs). However, when the bottom electrodes of the capacitors stay too close to each other, current may leak from the capacitors. Some reasons the bottom electrodes stay too close to each other include the trenches for depositing the bottom electrodes bend before depositing the bottom electrodes. Once the trenches bend, the bottom electrodes deposited therein bend accordingly, so some distances between the bottom electrodes may be too close to cause the current to leak. Some other reasons the bottom electrodes stay too close to each other include the bottom electrodes may be oxidized in the formation of the capacitors, and the hardness of the bottom electrodes decreases when the bottom electrodes are oxidized. The lower hardness of the bottom electrodes causes the bottom electrodes to bend easily. In addition, the oxidized portions of the bottom electrodes may also be removed in the operations to form the capacitors. When the oxidized portions are removed, the remaining thinner bottom electrodes also cause the bottom electrodes to bend easily. According to at least the reasons provided above, it is essential to develop a more satisfying capacitor structure and a method of forming the same.

### SUMMARY

The present disclosure provides a capacitor structure. The capacitor structure includes a bottom electrode, a first dielectric layer, and a first top electrode. The bottom electrode includes a bottom portion and a side portion, in which the side portion extends upward from an edge of the bottom portion, the side portion includes a first portion and a second portion on the first portion, and a first width of the first portion is smaller than a second width of the second portion. The first dielectric layer is on the bottom electrode. The first top electrode is on the first dielectric layer.

In some embodiments, the first portion and the second portion together surround the first dielectric layer and the first top electrode.

In some embodiments, a ratio of the second width to the first width is larger than 1 and smaller than or equal to 1.4.

In some embodiments, the side portion has a width tapering from top to bottom.

In some embodiments, a minimum of the first width is from 2 nm to 6 nm.

In some embodiments, a maximum of the second width is larger than 2 nm and smaller than or equal to 8.4 nm.

In some embodiments, the capacitor structure further includes a second dielectric layer surrounding the first portion and the second portion, and a second top electrode surrounding the second dielectric layer.

The present disclosure also provides a method of forming a capacitor structure. The method includes the following operations. A hard mask layer is formed on a substrate. A patterned photoresist layer including an opening is formed on the hard mask layer. A portion of the hard mask layer and a portion of the substrate are removed through the opening of the patterned photoresist layer to form a trench. A bottom electrode is formed in the trench. A protecting layer is formed on the bottom electrode. An oxide layer filling the trench and on the protecting layer and a remaining portion of the hard mask layer is formed. A portion of the oxide layer outside the trench and the remaining portion of the hard mask layer are removed. A remaining portion of the oxide layer in the trench and the protecting layer are removed to expose the bottom electrode. A first dielectric layer is formed on the bottom electrode. A first top electrode is formed on the first dielectric layer.

In some embodiments, the protecting layer separates the bottom electrode from the oxide layer.

In some embodiments, the protecting layer includes lanthanide oxide, titanium oxide, aluminum oxide, silicon oxide, zirconium oxide, hafnium oxide, tantalum oxide, yttrium oxide, scandium oxide, gallium oxide, niobium oxide, magnesium oxide, silicon nitride, silicon oxynitride, or combinations thereof.

In some embodiments, a thickness of the protecting layer is smaller than or equal to 10 nm.

In some embodiments, forming the protecting layer is performed by a thermal atomic layer deposition method at a temperature smaller than or equal to 400 °C.

In some embodiments, the bottom electrode includes a side portion on a sidewall surface of the trench, the side portion includes a first portion and a second portion on the first portion, and a first width of the first portion is smaller than a second width of the second portion.

In some embodiments, removing the portion of the oxide layer outside the trench and the remaining portion of the hard mask layer is performed by a chemical mechanical polishing method.

In some embodiments, the method further includes the following operations. A portion of the substrate outside the trench is removed after removing the remaining portion of the oxide layer and the protecting layer. A second dielectric layer is formed on a side of the bottom electrode opposite to a side of the bottom electrode on which the first dielectric layer is formed. A second top electrode is formed on the second dielectric layer.

### BRIEF DESCRIPTION OF THE DRAWINGS

The present disclosure can be more fully understood by reading the following detailed description of the embodiments, with reference made to the accompanying drawings.

FIG. 1A is a cross-sectional view of a capacitor structure according to some embodiments of the present disclosure.

FIGS. 1B and 1C are top views of a capacitor of the capacitor structure respectively along a line B-B and a line C-C of FIG. 1A, according to some embodiments of the present disclosure.

FIG. 2 is a flow chart of a method of forming a capacitor structure according to some embodiments of the present disclosure.

FIGS. 3A, 4A, 5A, 6A, 7A, 8A, 9A, 10A, 11A, 12A, 13A, and 14A are top views of the structures during the formation of the capacitor structure by the method of the present disclosure according to some embodiments.

FIGS. 3B, 4B, 5B, 6B, 7B, 8B, 9B, 10B, 11B, 12B, 13B, and 14B are cross-sectional views of the structures during the formation of the capacitor structure by the method of the present disclosure according to some embodiments.

FIGS. 15 and 16 are cross-sectional views of the structures during the formation of a capacitor structure according to some comparative embodiments of the present disclosure.

### DETAILED DESCRIPTION

To make the description of the present disclosure detailed and complete, the following is an illustrative description of the aspects of the embodiments. This is not to limit the embodiments of the present disclosure to only one form. The embodiments of the present disclosure may be combined or substituted with each other when it is beneficial, and other embodiments may be added without further explanation.

In addition, spatially relative terms, such as below and above, etc., may be used in the present disclosure to describe the relationship between one element (or feature) to another element (or feature) in the figures. In addition to the orientation depicted in the figures, spatially relative terms are intended to encompass different orientations of the device in use or in operation. For example, the device may be oriented otherwise (e.g., rotated 90 degrees), and the spatially relative terms can be interpreted accordingly. In the present disclosure, unless otherwise indicated, the same element numbers in different figures refer to the same or similar elements formed from the same or similar materials by the same or similar methods.

The terms “around”, “approximately”, “nearly”, “basically”, "substantially", etc., used in the present disclosure include the stated values (or characteristics) and a deviation of the stated values (or characteristics) understood by one skilled in the art. For example, considering the errors of the values (or characteristics), these terms may indicate the values within one or more standard deviations (e.g., the values within ±30%, ±20%, ±15%, ±10%, or ±5%), or may indicate the characteristics including the deviation from the practical operation (e.g., the “substantially parallel” may indicate close to parallel in practical, rather than a perfect ideally parallelism). Furthermore, it is possible to select an acceptable range of the deviation according to the nature of the measurement or other properties, instead of applying only one single deviation range to all the values (or characteristics).

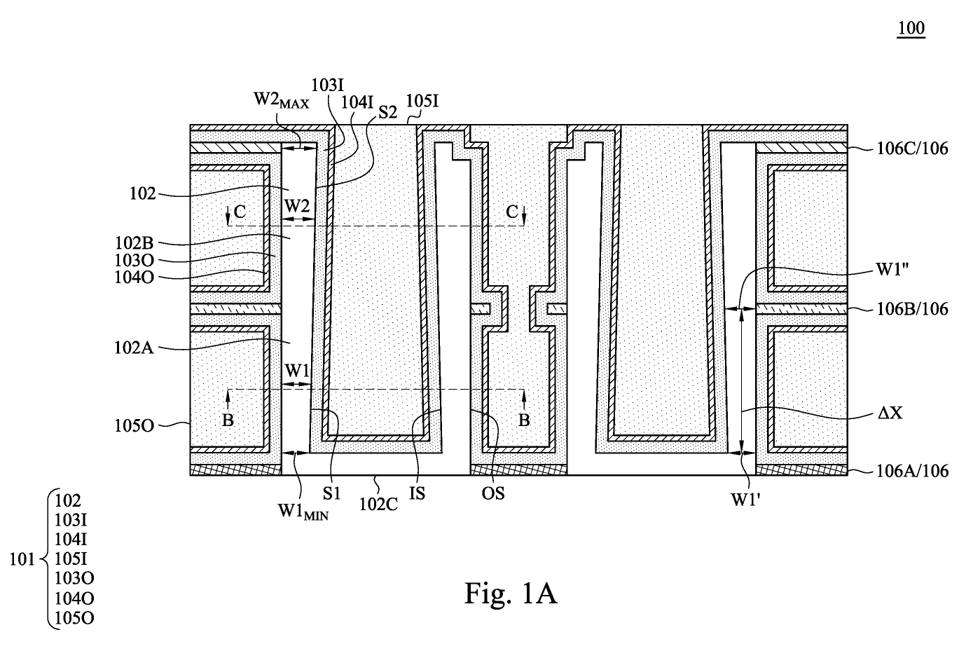

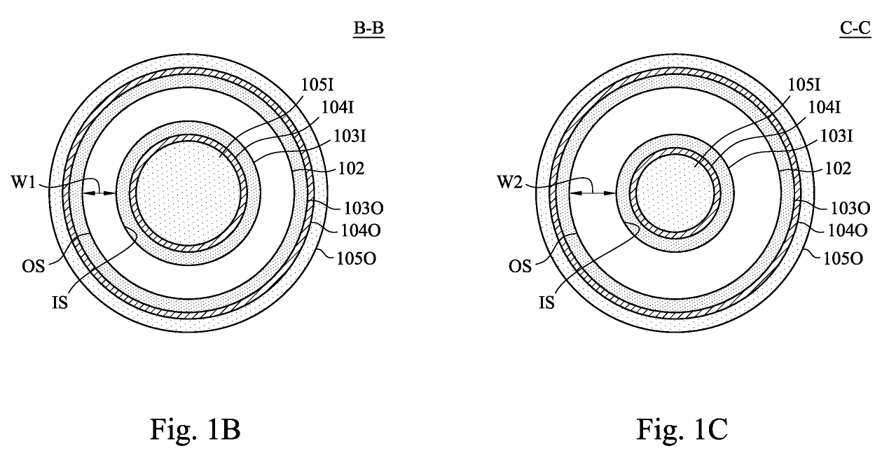

The present disclosure provides a capacitor structure 100, as shown in FIGS. 1A to 1C. The capacitor structure 100 includes at least one capacitor 101 including a bottom electrode 102, a first dielectric layer 103I, and a first top electrode 104I to store electrical charges in the first dielectric layer 103I disposed between the bottom electrode 102 and the first top electrode 104I. The bottom electrode 102 includes a bottom portion 102C and a side portion, in which the side portion extends upward from an edge of the bottom portion 102C, the side portion includes a first portion 102A and a second portion 102B disposed on the first portion 102A, and a first width W1 of the first portion 102A is smaller than a second width W2 of the second portion 102B. The first dielectric layer 103I is on the bottom electrode 102, and the first top electrode 104I is on the first dielectric layer 103I. The bottom electrode 102 of the present disclosure is not bent easily to improve the performance of the capacitor 101. Moreover, since the bottom electrode 102 is not bent easily, the bottom electrode 102 is prevented from staying too close to another bottom electrode of another capacitor disposed nearby, thereby preventing the current in the capacitors from leaking to each other. Next, the capacitor structure 100 of the present disclosure is discussed in detail by the following embodiments.

In some embodiments, the capacitor 101 of the present disclosure is formed in a substrate 106. For details of forming the capacitor 101 please refer to the discussion about the method 200 of the present disclosure below. In some embodiments, the number of the capacitors 101 in the substrate 106 is not limited. For example, two capacitors 101 are present in FIG. 1A. However, in some embodiments, more capacitors 101 can be present and arranged into a two-dimensional array. In some embodiments, the substrate 106 includes a bottom supporting layer 106A, a middle supporting layer 106B, and a top supporting layer 106C disposed beside the bottom electrode 102 to support the capacitor 101 from bottom to top. Therefore, with the help of the bottom supporting layer 106A, the middle supporting layer 106B, and the top supporting layer 106C, the bottom electrode 102 may not bend easily, and when the number of the capacitors 101 is more than one, the bottom supporting layer 106A, the middle supporting layer 106B, and the top supporting layer 106C can also help the bottom electrodes 102 stay at a distance from each other to avoid the current leakage between the capacitors 101. In addition, the bottom supporting layer 106A, the middle supporting layer 106B, and the top supporting layer 106C disposed respectively next to the bottom, the middle, and the top of the bottom electrode 102 provide an even support to the bottom electrode 102. When the capacitor 101 is formed in a high aspect ratio to have a longer bottom electrode 102 from bottom to top, such distribution of the bottom supporting layer 106A, the middle supporting layer 106B, and the top supporting layer 106C ensures the support to the bottom electrode 102 is still strong enough. In some embodiments, the bottom supporting layer 106A, the middle supporting layer 106B, and the top supporting layer 106C independently include silicon nitride.

The bottom electrode 102 includes the first portion 102A and the second portion 102B from the bottom to the top of the capacitor 101. In some embodiments, the first portion 102A and the second portion 102B of the bottom electrode 102 extend along the side of the capacitor 101. The first portion 102A has the first width W1 and the second portion 102B has the second width W2 from the cross-sectional view of the capacitor 101, and the first width W1 is smaller than the second width W2. Since the bottom electrode 102 of the present disclosure is protected by the protecting layer 109 described below during the formation of the capacitor 101, the bottom electrode 102 is substantially not oxidized and the first width W1 of the first portion 102A and the second width W2 of the second portion 102B remain substantially intact as the shape when they were just formed. In other words, in the resultant capacitor structure 100, the bottom electrode 102 is unoxidized to avoid the hardness loss of the bottom electrode 102 and the width of the bottom electrode 102 is not reduced during the process to avoid becoming too narrow to cause the bottom electrode to bend. In some embodiments, the hardness of the bottom electrode 102 is preferably from 9.5 GPa to 11.5 GPa, for example, 9.5 GPa, 10 GPa, 10.5 GPa, 11 GPa, or 11.5 GPa. In some embodiments, a ratio of the second width W2 to the first width W1 is preferably larger than 1 and smaller than or equal to 1.4, for example, 1.1, 1.2, 1.3, or 1.4. In some embodiments, the bottom electrode 102 includes titanium nitride, titanium silicon nitride, or a combination thereof.

For a more detailed description of the bottom electrode 102, in some embodiments, the first width W1 of the first portion 102A gradually increases from bottom to top with a first slope, and the second width W2 of the second portion 102B gradually increases from bottom to top with a second slope. Therefore, a surface S1 of the first portion 102A and a surface of the second portion 102B are substantially flat, even though the widths increase from bottom to top. Specifically, the first slope is the change in the first width W1 divided by the corresponding change in distance between the bottom and the top of the first portion 102A, and the second slope is the change in the second width W2 divided by the corresponding change in distance between the bottom and the top of the second portion 102B. Taking the first slope as an example in FIG. 1A, the first width W1 of the first portion 102A at the top may have a value W1’’ and at the bottom may have a value W1’, and the distance between the top and the bottom may be the value ΔX, so the first slope is (W1’’- W1’)/ΔX. A larger slope means a dramatic change in the widths, and a smaller slope means a rather consistent width. In some embodiments, the first portion 102A continuously extends to the second portion 102B, and the first slope is equal to the second slope, so the surface S1 continuously extends to the surface S2, and the connection between the surface S1 and the surface S2 is also flat.

In some embodiments, a minimum W1ₘᵢₙ of the first width W1 is preferably from 2 nm to 6 nm, for example, 2 nm, 3 nm, 4 nm, 5 nm, or 6 nm. When the minimum W1ₘᵢₙ is too small, the first portion 102A of the bottom electrode 102 may be too narrow to work as an electrode effectively and the bottom electrode 102 may bend easily. When the minimum W1ₘᵢₙ is too large, the size of the capacitor 101 may be too large without a significant improvement in the performance of the capacitor 101. In some embodiments, a maximum W2_{MAX} of the second width W2 is preferably larger than 2 nm and smaller than or equal to 8.4 nm, for example, 2.5 nm, 3 nm, 4 nm, 5 nm, 6 nm, 7 nm, 8 nm, or 8.4 nm. When the maximum W2_{MAX} is too small, the second portion 102B of the bottom electrode 102 may be too narrow to work as an electrode effectively and the bottom electrode 102 may bend easily. When the maximum W2_{MAX} is too large, the size of the capacitor 101 may be too large without a significant improvement in the performance of the capacitor 101.

In some embodiments, the bottom electrode 102 includes the bottom portion 102C extending continuously to the first portion 102A and disposed on the bottom of the capacitor 101. In some embodiments, the bottom portion 102C is disposed below the first portion 102A, the second portion 102B, the first dielectric layer 103I, and the first top electrode 104I.

Above the bottom electrode 102, the first dielectric layer 103I is disposed on the bottom electrode 102, and the first top electrode 104I is disposed on the first dielectric layer 103I. In some embodiments, the first dielectric layer 103I includes any suitable high-k dielectric material, for example, hafnium zirconium oxide, zirconium oxide, hafnium oxide, aluminum oxide, rhodium oxide, ruthenium oxide, or combinations thereof. In some embodiments, the first top electrode 104I includes titanium nitride, titanium silicon nitride, or a combination thereof. In some embodiments, a first filling layer 105I is disposed on the first top electrode 104I, as shown in FIG. 1A. However, in other embodiments, although not drawn in the figures, the first filling layer 105I shown in FIG. 1A is replaced by the extension of the first top electrode 104I, and the capacitor 101 excludes the first filling layer 105I. In the embodiments including the first filling layer 105I, the first filling layer 105I may include polycrystalline silicon germanium (poly SiGe) to behave like the first top electrode 104I to improve the conductivity when working with the first top electrode 104I.

In some embodiments, as the cross-sectional views shown in FIGS. 1B and 1C, the capacitor 101 is close to a cylinder. The first portion 102A and the second portion 102B of the bottom electrode 102 surround the first dielectric layer 103I, and the first dielectric layer 103I surrounds the first top electrode 104I. The first dielectric layer 103I and the first top electrode 104I are inner in the capacitor 101 compared with the first portion 102A and the second portion 102B of the bottom electrode 102. In the embodiments including the first filling layer 105I, the first top electrode 104I surrounds the first filling layer 105I. In these embodiments, the first filling layer 105I is also inner in the capacitor 101 compared with the first portion 102A and the second portion 102B of the bottom electrode 102.

In some embodiments, the capacitor 101 further includes a second dielectric layer 103O on the bottom electrode 102 and a second top electrode 104O on the second dielectric layer 103O, in which the second dielectric layer 103O is disposed between the bottom electrode 102 and the second top electrode 104O to further increase the capacitance of the capacitor 101. Specifically, the first dielectric layer 103I and the first top electrode 104I are on a side IS of the bottom electrode 102, and the second dielectric layer 103O and the second top electrode 104O are on a side OS of the bottom electrode 102 opposite to the side IS. In some embodiments, the second dielectric layer 103O includes any suitable high-k dielectric material, for example, hafnium zirconium oxide, zirconium oxide, hafnium oxide, aluminum oxide, rhodium oxide, ruthenium oxide, or combinations thereof. In some embodiments, the second top electrode 104O includes titanium nitride, titanium silicon nitride, or a combination thereof. In some embodiments, a second filling layer 105O is disposed on the second top electrode 104O, as shown in FIG. 1A. However, in other embodiments, although not drawn in the figures, the second filling layer 105O shown in FIG. 1A is replaced by the extension of the second top electrode 104O, and the capacitor 101 excludes the second filling layer 105O. In the embodiments including the second filling layer 105O, the second filling layer 105O may include polycrystalline silicon germanium (poly SiGe) to behave like the second top electrode 104O to improve the conductivity when working with the second top electrode 104O.

In the embodiments that the capacitor 101 is close to a cylinder, as shown in the cross-sectional views of FIGS. 1B and 1C, the side IS of the bottom electrode 102 is closer to the center of the cylinder compared with the side OS of the bottom electrode 102. The second top electrode 104O surrounds the second dielectric layer 103O, and the second dielectric layer 103O surrounds the first portion 102A and the second portion 102B of the bottom electrode 102. The second dielectric layer 103O and the second top electrode 104O are outer in the capacitor 101 compared with the first portion 102A and the second portion 102B of the bottom electrode 102. In the embodiments including the second filling layer 105O, the second filling layer 105O surrounds the second top electrode 104O. In these embodiments, the second filling layer 105O is also outer in the capacitor 101 compared with the first portion 102A and the second portion 102B of the bottom electrode 102.

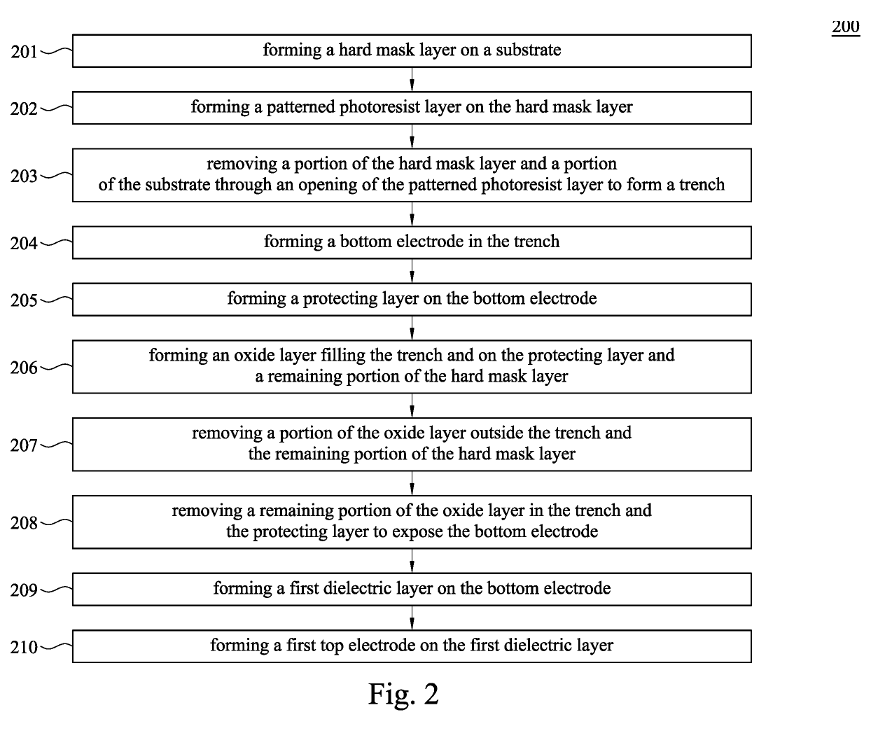

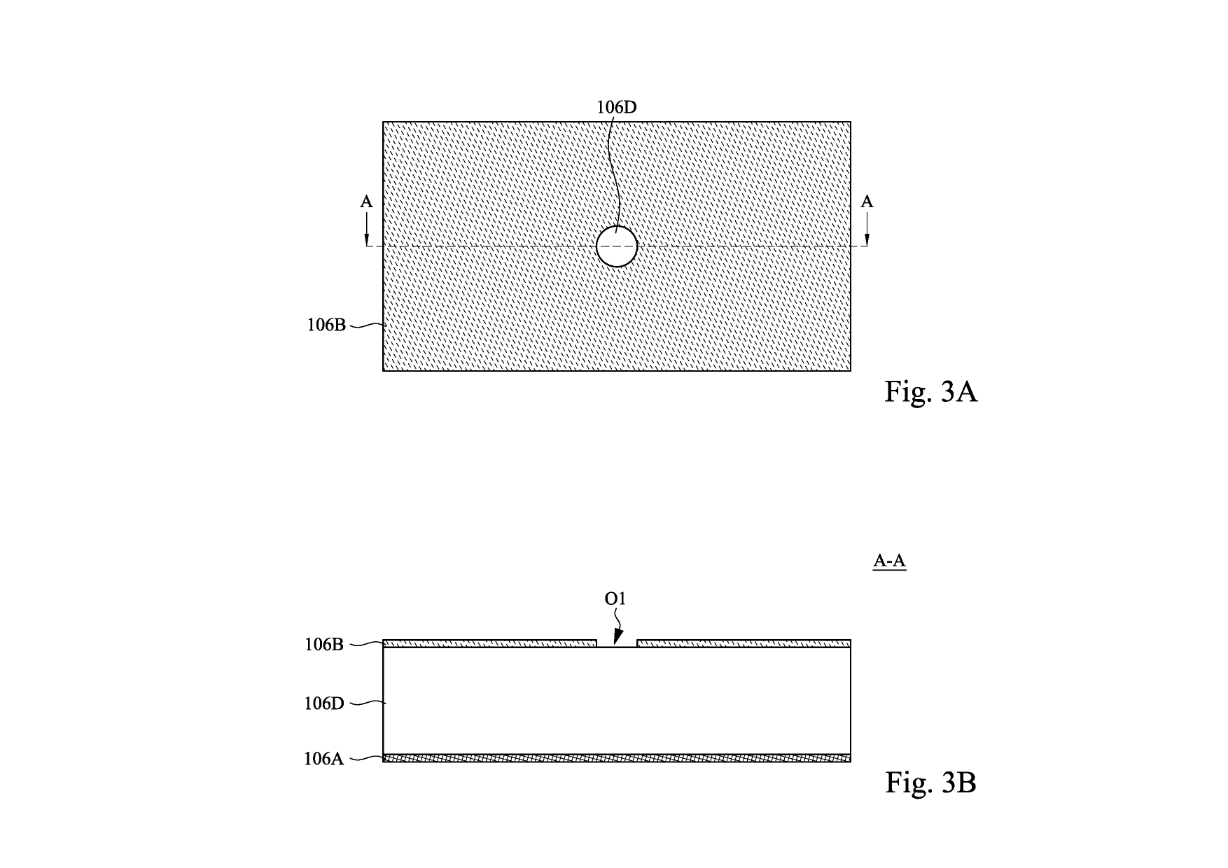

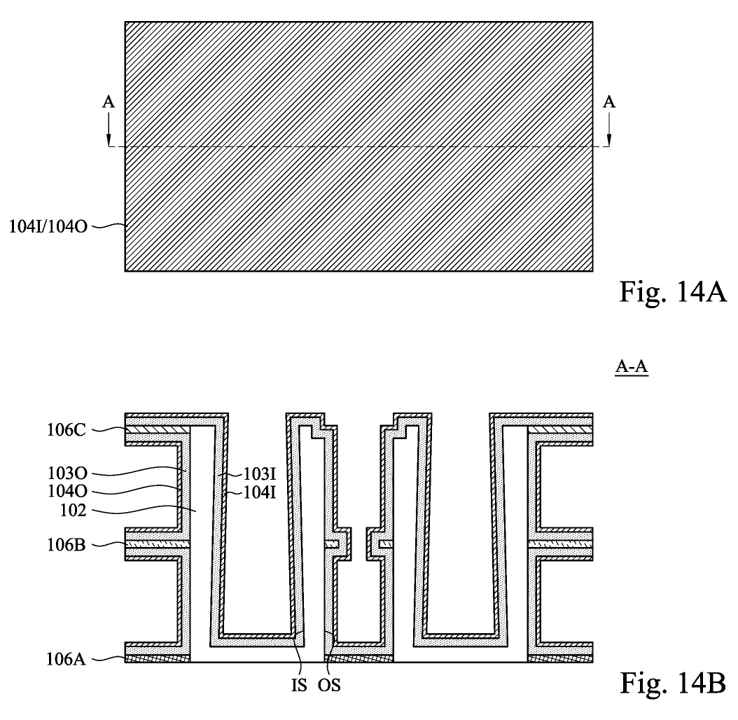

The present disclosure also provides a method 200 of forming the capacitor structure 100 described above. The method 200 includes an operation 201 to an operation 210, as shown in FIG. 2. The structural change to form the capacitor structure 100 by the method 200 can refer to FIGS. 3A to 14B and 1A to 1C, in which FIGS. 3B, 4B, 5B, 6B, 7B, 8B, 9B, 10B, 11B, 12B, 13B, and 14B are cross-sectional views respectively taken from the top views of FIGS. 3A, 4A, 5A, 6A, 7A, 8A, 9A, 10A, 11A, 12A, 13A, and 14A along a line A-A. The operation 201 includes forming a hard mask layer 107 on the substrate 106. The operation 202 includes forming a patterned photoresist layer 108 including an opening O2 on the hard mask layer 107. The operation 203 includes removing a portion 107a of the hard mask layer 107 and a portion 106a of the substrate 106 through the opening O2 of the patterned photoresist layer 108 to form a trench T1. The operation 204 includes forming the bottom electrode 102 in the trench T1. The operation 205 includes forming a protecting layer 109 on the bottom electrode 102. The operation 206 includes forming an oxide layer 110 filling the trench T1 and on the protecting layer 109 and a remaining portion 107b of the hard mask layer 107. The operation 207 includes removing a portion 110a of the oxide layer 110 outside the trench T1 and the remaining portion 107b of the hard mask layer 107. The operation 208 includes removing a remaining portion 110b of the oxide layer 110 in the trench T1 and the protecting layer 109 to expose the bottom electrode 102. The operation 209 includes forming the first dielectric layer 103I on the bottom electrode 102. The operation 210 includes forming the first top electrode 104I on the first dielectric layer 103I. Next, the method 200 of the present disclosure is discussed in detail by the following embodiments.

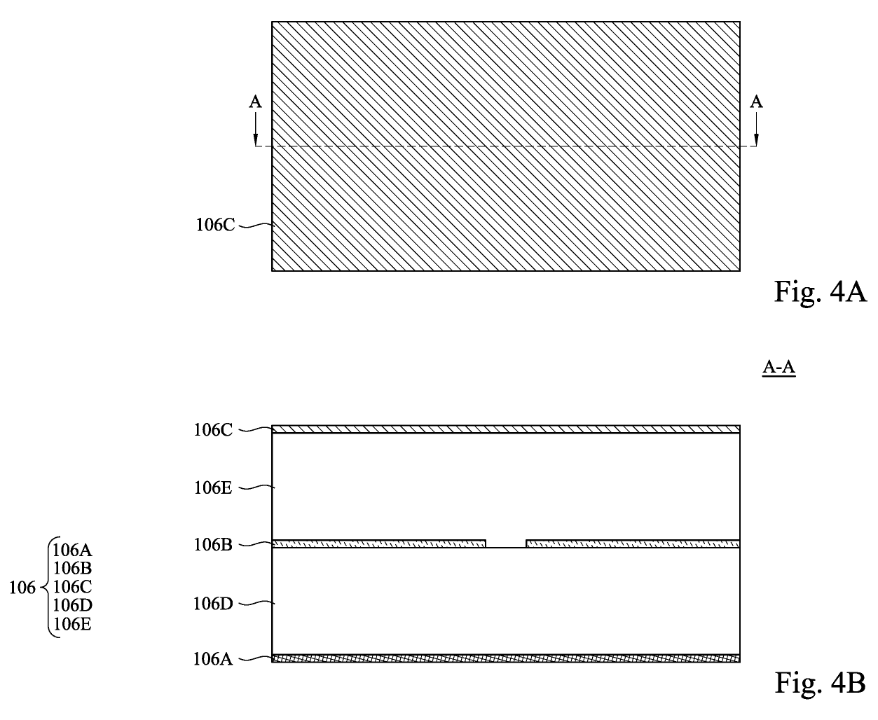

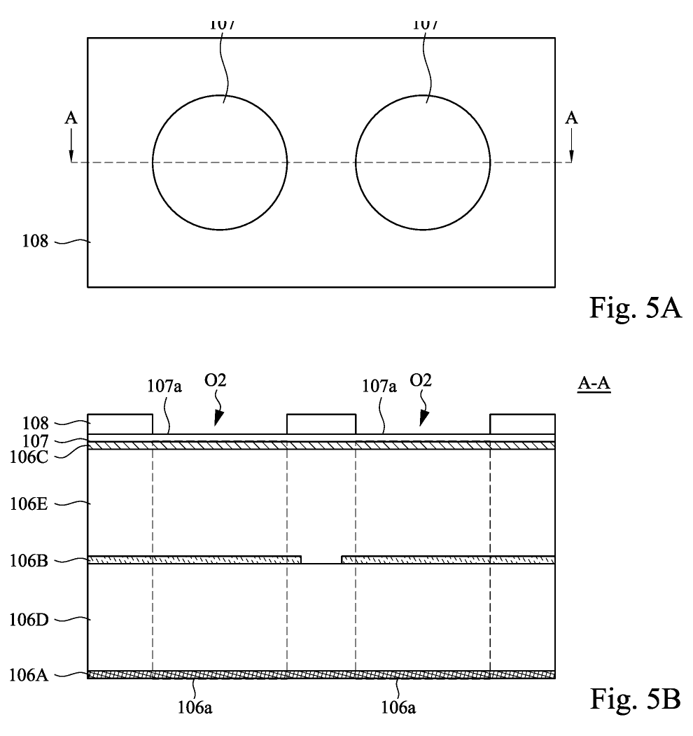

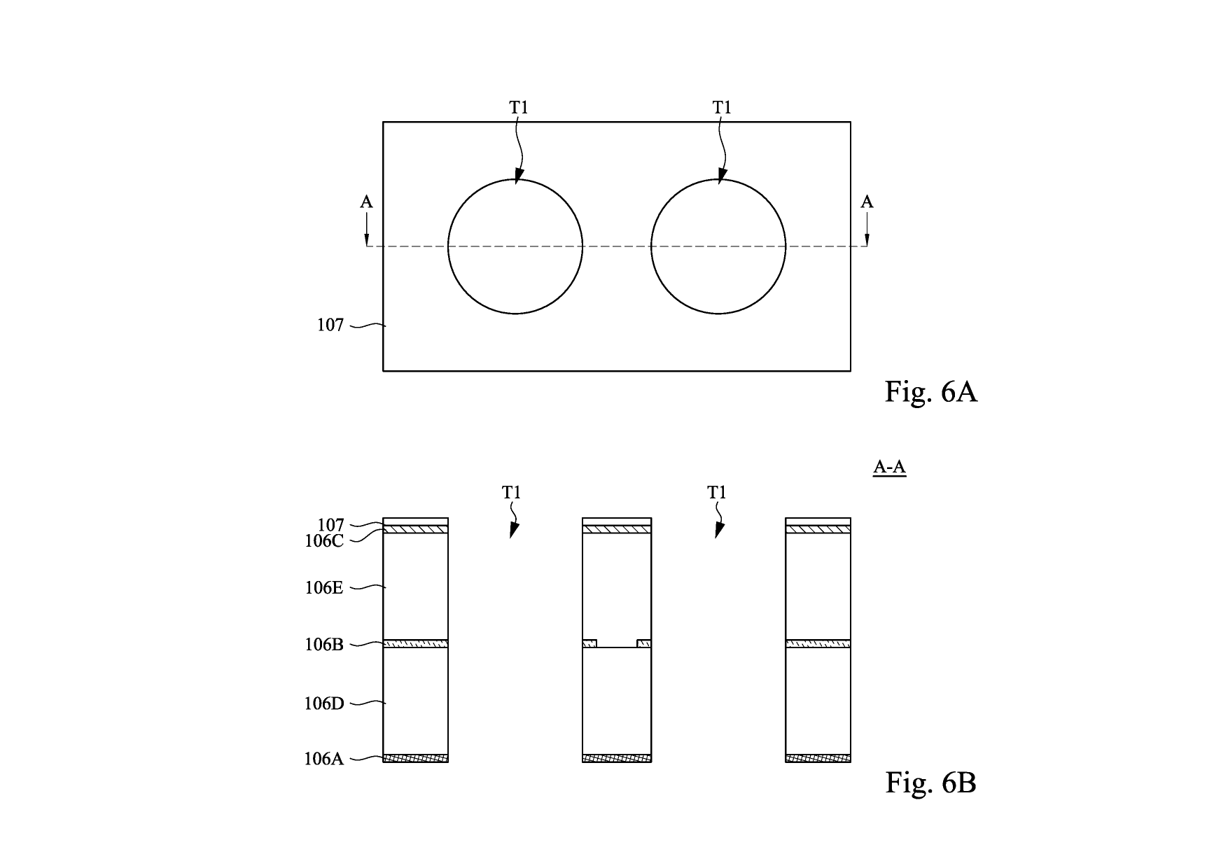

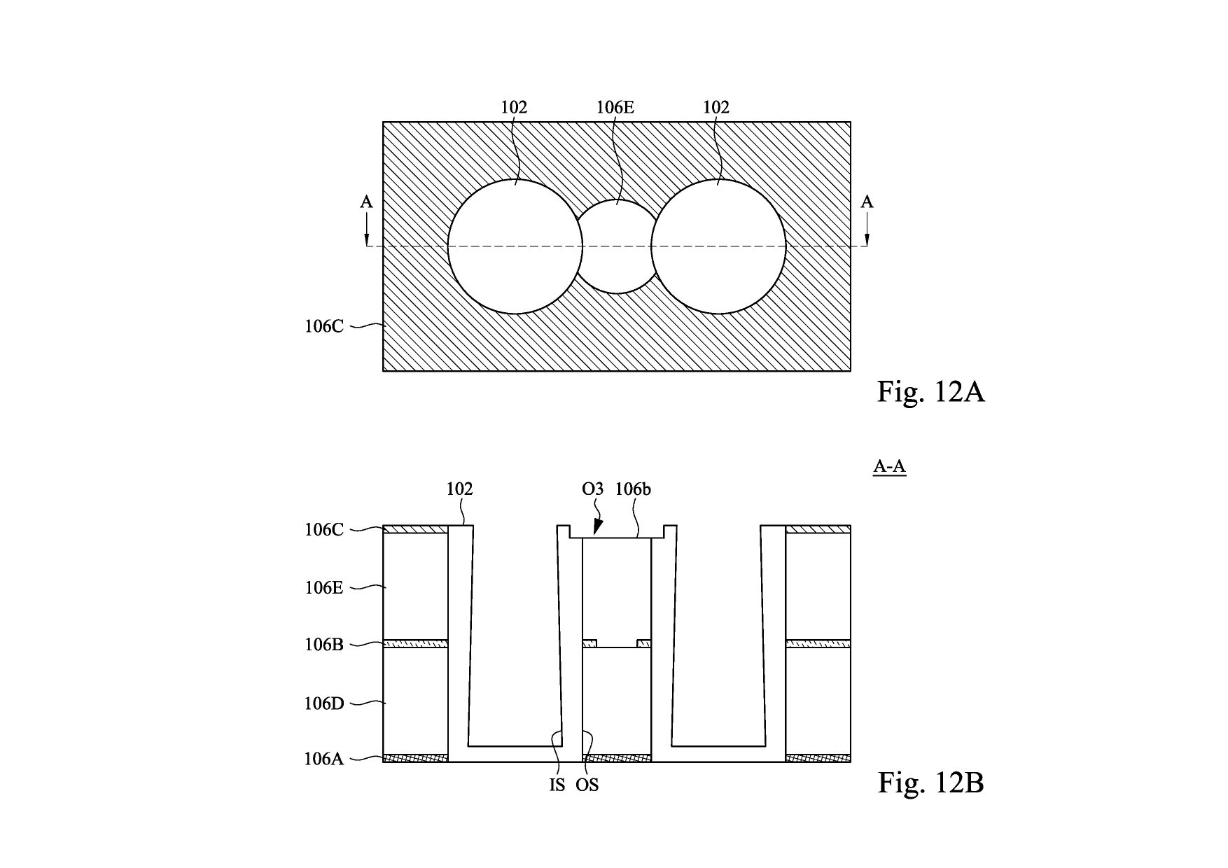

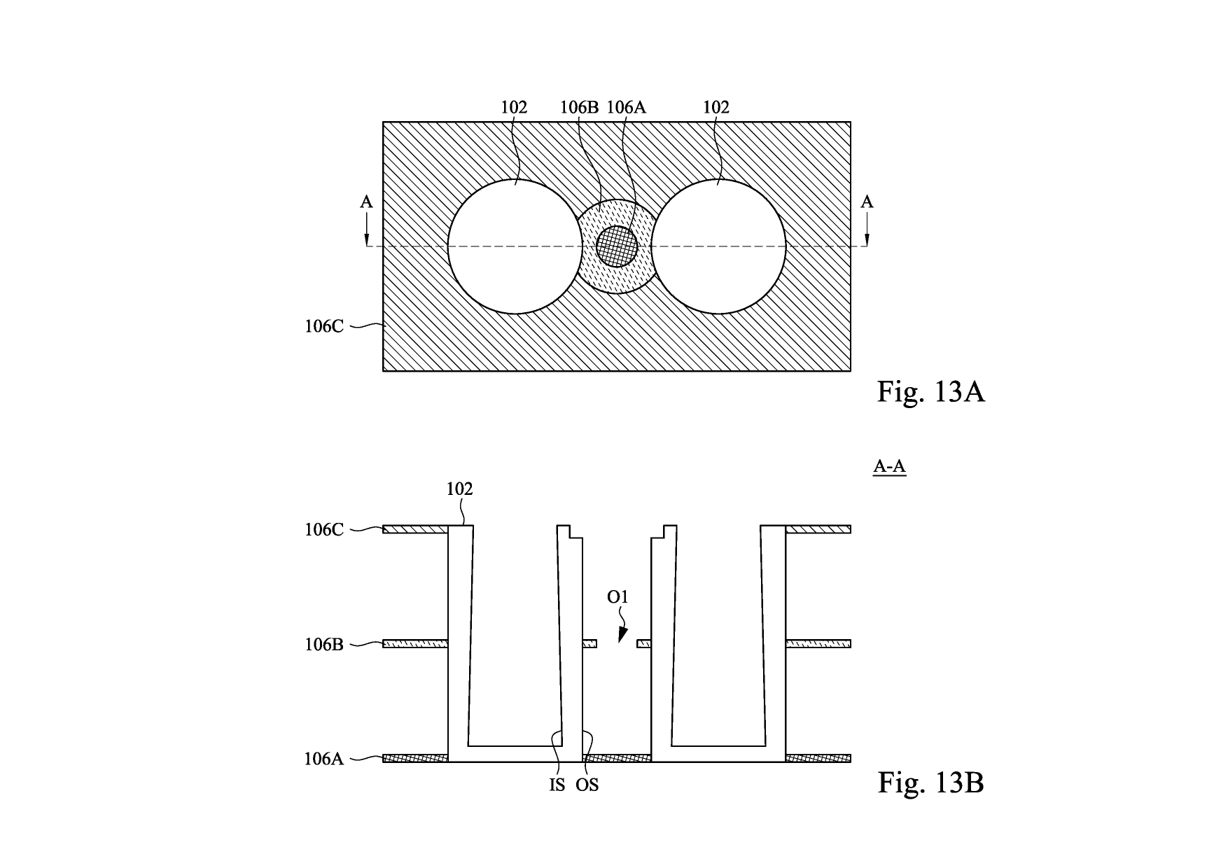

Refer to FIGS. 3A to 4B. Before performing the operation 201, the method 200 may further include forming the substrate 106 to act as a supporting substrate during the formation of the capacitor 101 of the present disclosure. In some embodiments, forming the substrate 106 includes forming an oxide layer 106D on the bottom supporting layer 106A, forming the middle supporting layer 106B on the oxide layer 106D, forming an oxide layer 106E on the middle supporting layer 106B, and forming the top supporting layer 106C on the oxide layer 106E. Portions of the bottom supporting layer 106A, the oxide layer 106D, the middle supporting layer 106B, the oxide layer 106E, and the top supporting layer 106C will be removed in the following operation 203 to form the trench T1 for the capacitor 101 (e.g., see FIGS. 5A to 6B). In the embodiments including the second dielectric layer 103O and the second top electrode 104O, portions of the top supporting layer 106C, the oxide layer 106D, and the oxide layer 106E outside the trench T1 may also be removed (e.g., see FIGS. 12A to 13B), in order to form the second dielectric layer 103O and the second top electrode 104O on the side OS of the bottom electrode 102, which will be discussed further in the following operations. In these embodiments including the second dielectric layer 103O and the second top electrode 104O, a portion of the middle supporting layer 106B may be removed to form an opening O1 in the middle supporting layer 106B after forming the middle supporting layer 106B on the oxide layer 106D and before forming the oxide layer 106E on the middle supporting layer 106B. The opening O1 provides an opening from the oxide layer 106E to the oxide layer 106D, so when removing the portions of the oxide layer 106D and the oxide layer 106E outside the trench T1, such portions may be removed together in a single process without performing separating operations to remove the portion of the oxide layer 106E and the portion of the oxide layer 106D. In some embodiments, the bottom supporting layer 106A may form on any component (not drawn) of a semiconductor structure. In some embodiments, forming the bottom supporting layer 106A, forming the oxide layer 106D, forming the middle supporting layer 106B, forming the oxide layer 106E, and forming the top supporting layer 106C are respectively performed by any suitable deposition method, for example, a chemical vapor deposition method or a physical vapor deposition method. In some embodiments, the oxide layer 106D and the oxide layer 106E include silicon dioxide.

Refer to FIGS. 5A to 6B. The operation 201 includes forming the hard mask layer 107 on the substrate 106, the operation 202 includes forming the patterned photoresist layer 108 including the opening O2 on the hard mask layer 107, and the operation 203 includes removing the portion 107a of the hard mask layer 107 and the portion 106a of the substrate 106 through the opening O2 of the patterned photoresist layer 108 to form the trench T1. The opening O2 of the patterned photoresist layer 108 defines the position where the trench T1 is formed in the operation 203. Specifically, the portion 107a of the hard mask layer 107 and the portion 106a of the substrate 106 (including portions of the bottom supporting layer 106A, the oxide layer 106D, the middle supporting layer 106B, the oxide layer 106E, and the top supporting layer 106C) underneath the opening O2 are removed, and the portions of the hard mask layer 107 and the substrate 106 covered by the patterned photoresist layer 108 are not removed. In other words, the pattern of the opening O2 in the patterned photoresist layer 108 transfers to the hard mask layer 107 and further to the substrate 106 in the operation 203. Compared with using only the patterned photoresist layer 108 and excluding the hard mask layer 107 to form the trench T1, the hard mask layer 107 has a higher resistance to be removed than the patterned photoresist layer 108, so the pattern transferred into the hard mask layer 107 can remain consistent throughout transferring such pattern further into the substrate 106. Therefore, the width of the trench T1 is substantially the same as the width of the opening O2, and in the embodiments including forming more than one capacitors 101, the positions of the trenches T1 are defined accurately by the openings O2 to avoid unwanted displacement of the trenches T1 causing the bottom electrodes 102 formed in the trenches T1 to be too close to each other to cause the current leakage. In some embodiments, forming the hard mask layer 107 and forming the patterned photoresist layer 108 are respectively performed by any suitable deposition method, for example, a chemical vapor deposition method or a physical vapor deposition method. In some embodiments, removing the portion 107a of the hard mask layer 107 and the portion 106a of the substrate 106 is performed by any suitable etching method, for example, a dry etching method. In some embodiments, removing the portion 107a of the hard mask layer 107 and the portion 106a of the substrate 106 includes also removing the patterned photoresist layer 108. In some embodiments, the patterned photoresist layer 108, if present after the operation 203, is removed by any suitable etching method, for example, a dry etching method or a wet etching method. In some embodiments, the trench T1 has a cylinder shape.

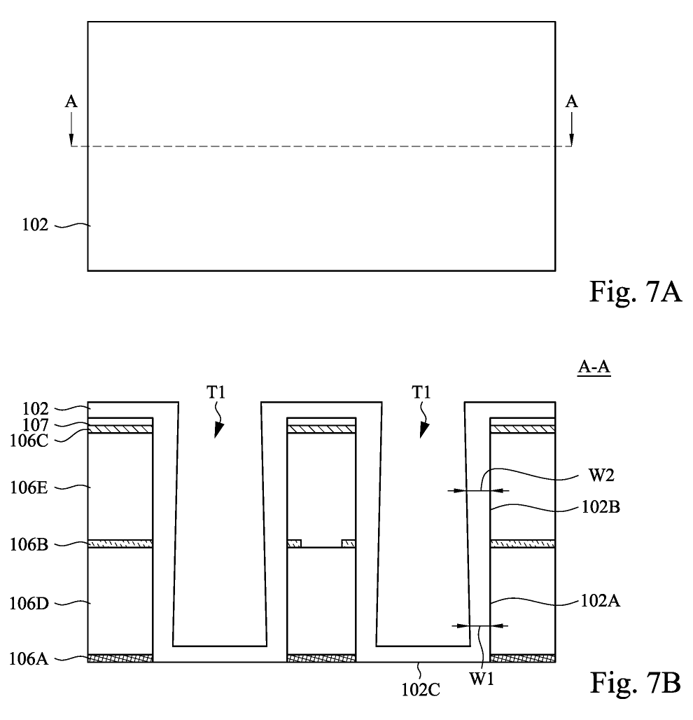

Refer to FIGS. 6A to 7B. The operation 204 includes forming the bottom electrode 102 in the trench T1. The bottom electrode 102 includes the first portion 102A and the second portion 102B disposed on the first portion 102A, as described above, and the first width W1 of the first portion 102A is smaller than the second width W2 of the second portion 102B. In addition, the bottom electrode 102 may further include the bottom portion 102C disposed below the first portion 102A and the second portion 102B, as described above. For the details of the bottom electrode 102, please refer to the disclosure provided above. The first portion 102A and the second portion 102B are disposed on the sidewall surface of the trench T1. The bottom portion 102C is disposed on the bottom surface of the trench T1. In some embodiments, the bottom electrode 102 is substantially conformally formed in the trench T1. In some embodiments, forming the bottom electrode 102 is performed by any suitable deposition method, for example, an atomic layer deposition method.

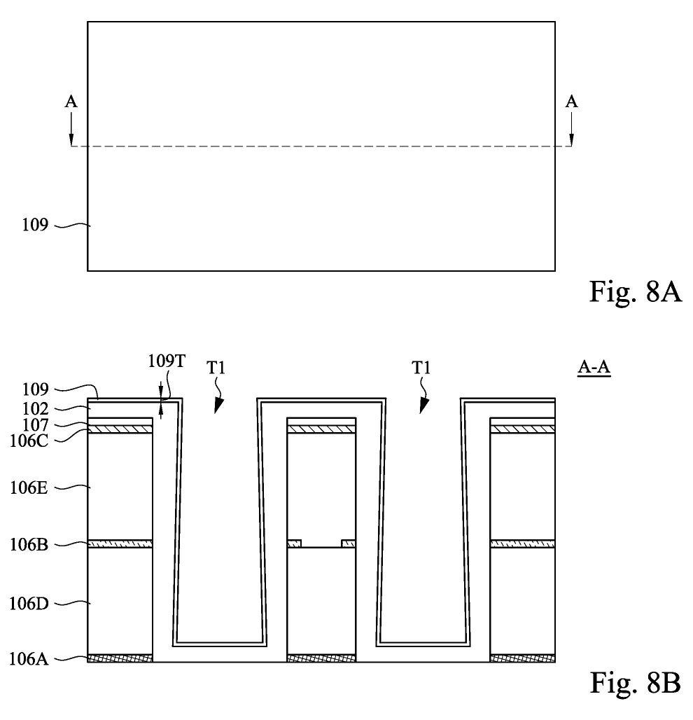

Refer to FIGS. 7A to 8B. The operation 205 includes forming the protecting layer 109 on the bottom electrode 102. The protecting layer 109 protects the bottom electrode 102 from being oxidized in the following operations. For example, the protecting layer 109 prevents the bottom electrode 102 from contacting the oxide layer 110 formed in the operation 206, so the oxidation of the bottom electrode 102 can be avoided when forming the oxide layer 110. Once the bottom electrode 102 is oxidized, the hardness of the bottom electrode 102 dramatically decreases and the bottom electrode 102 is easily bent. On the other hand, the oxidized bottom electrode 102 may also be removed easily in the following operations, for example, in the operation 208, so once the bottom electrode 102 is oxidized, the widths (e.g., the first width W1 and the second width W2) of the bottom electrode 102 may also decrease and cause the bottom electrode 102 to bend easily. As described above, the bent bottom electrode 102 decreases the performance of the bottom electrode 102, and in the embodiments including more than one capacitor 101, the bent bottom electrode 102 also increases the probability of the current leakage between the capacitors 101. In some embodiments, the protecting layer 109 preferably includes lanthanide oxide (e.g., lanthanum oxide, gadolinium oxide, or the like), titanium oxide, aluminum oxide, silicon oxide, zirconium oxide, hafnium oxide, tantalum oxide, yttrium oxide, scandium oxide, gallium oxide, niobium oxide, magnesium oxide, silicon nitride, silicon oxynitride, or combinations thereof. In some embodiments, a thickness 109T of the protecting layer 109 is preferably smaller than or equal to 10 nm and larger than or equal to 0.2 nm, for example, 0.2 nm, 0.5 nm, 1 nm, 2 nm, 5 nm, 7.5 nm, or 10 nm, in which 0.5 nm to 5 nm is more preferable. When the thickness 109T is too small, the protection of the protecting layer 109 to the bottom electrode 102 may not be enough. When the thickness 109T is too large, forming the protecting layer 109 may also oxidize the bottom electrode 102. In some embodiments, forming the protecting layer 109 is performed by a thermal atomic layer deposition method at a temperature preferably smaller than or equal to 400 °C and larger than or equal to 50 °C, for example, 50 °C, 100 °C, 150 °C, 200 °C, 250 °C, 300 °C, 350 °C, or 400 °C, in which 150 °C to 300 °C is more preferable. When the temperature is too small, the protecting layer 109 may not be formed. When the temperature is too large, forming the protecting layer 109 may also oxidize the bottom electrode 102. In some embodiment, forming the protecting layer 109 is not performed by using plasma, for example, excluding using the plasma atomic layer deposition method, to avoid the energy of the plasma being too high to cause the bottom electrode 102 to oxidize.

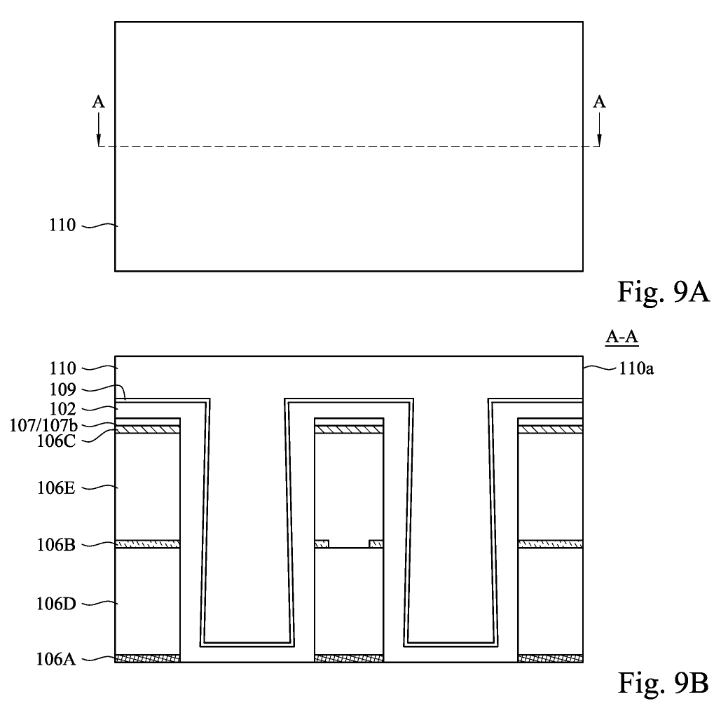

Refer to FIGS. 8A to 10B. The operation 206 includes forming the oxide layer 110 filling the trench T1 and on the protecting layer 109 and the remaining portion 107b of the hard mask layer 107, and the operation 207 includes removing the portion 110a of the oxide layer 110 outside the trench T1 and the remaining portion 107b of the hard mask layer 107. After the operation 206, the protecting layer 109 separates the bottom electrode 102 from the oxide layer 110. The oxide layer 110 filling the trench T1 and on the remaining portion 107b of the hard mask layer 107 increases the rigidity of the structure before performing the operation 207. Specifically, to remove the hard mask layer 107, without the oxide layer 110 protecting the trench T1, the size of the trench T1 may change and/or the position of the trench T1 may be displaced from the original position when performing the operation to remove the hard mask layer 107. When the size change and the displacement of the trench T1 occur, the bottom electrode 102 formed thereon may bend, thereby increasing the probability of the current leakage. In some embodiments, after the operation 206 and before the operation 207, the oxide layer 110 covers the whole upper surface of the structure shown in FIGS. 9A and 9B. In some embodiments, after the operation 206 and before the operation 207, the upper surface of the oxide layer 110 is substantially a flat surface. In some embodiments, after the operation 206 and before the operation 207, the oxide layer 110 at least completely fills an upper portion of the trench T1. In some embodiments, forming the oxide layer 110 in the operation 206 is performed by any suitable deposition method, for example, a plasma atomic layer deposition method. In some embodiments, the oxide layer 110 includes silicon dioxide. In some embodiments, removing the portion 110a of the oxide layer 110 and the remaining portion 107b of the hard mask layer 107 outside the trench T1 in the operation 207 includes removing a portion of the protecting layer 109 and a portion of the bottom electrode 102 outside the trench T1. In some embodiments, removing the portion 110a of the oxide layer 110 and the remaining portion 107b of the hard mask layer 107 outside the trench T1 in the operation 207 is performed by a chemical mechanical polishing method. In some embodiments, the chemical mechanical polishing method is performed until the hard mask layer 107 is substantially removed completely. The oxide layer 110 filling the trench T1 can also prevent the slurry used in the chemical mechanical polishing method to contaminate the trench T1.

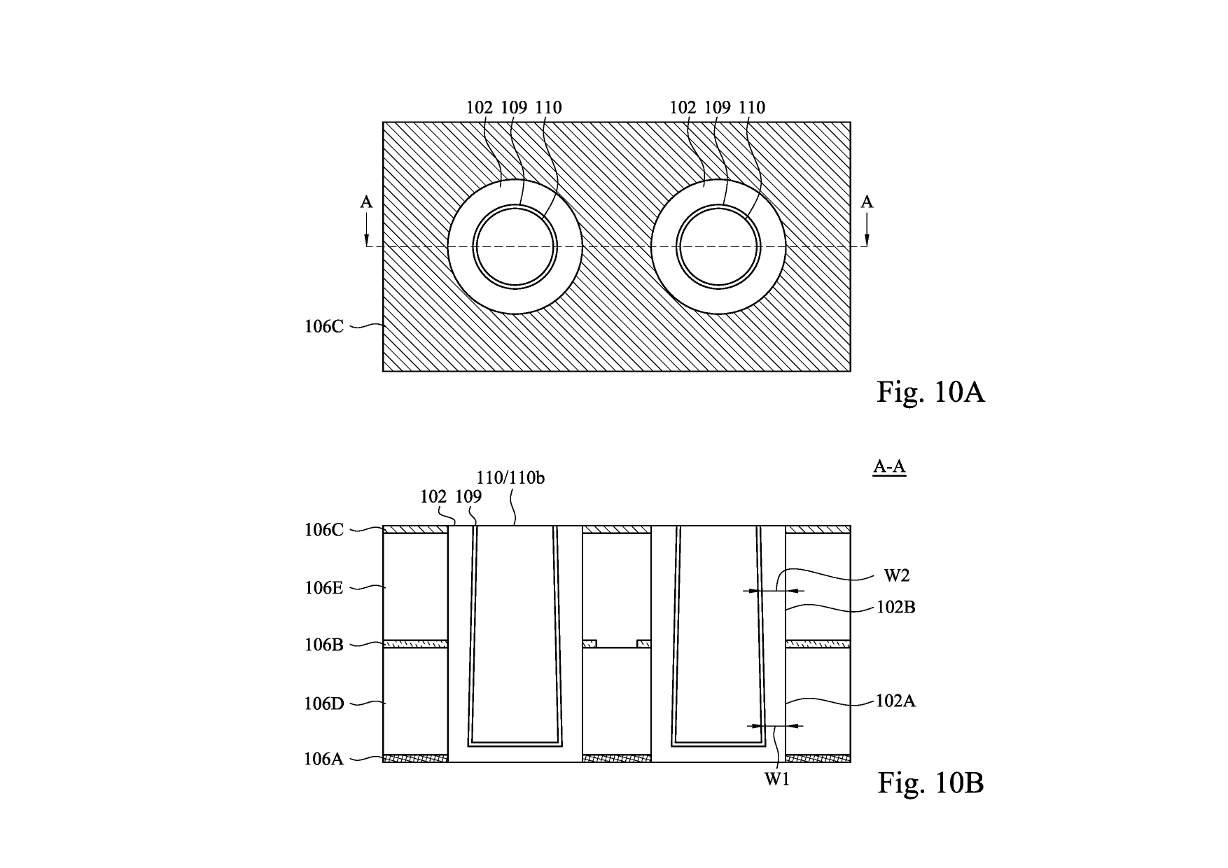

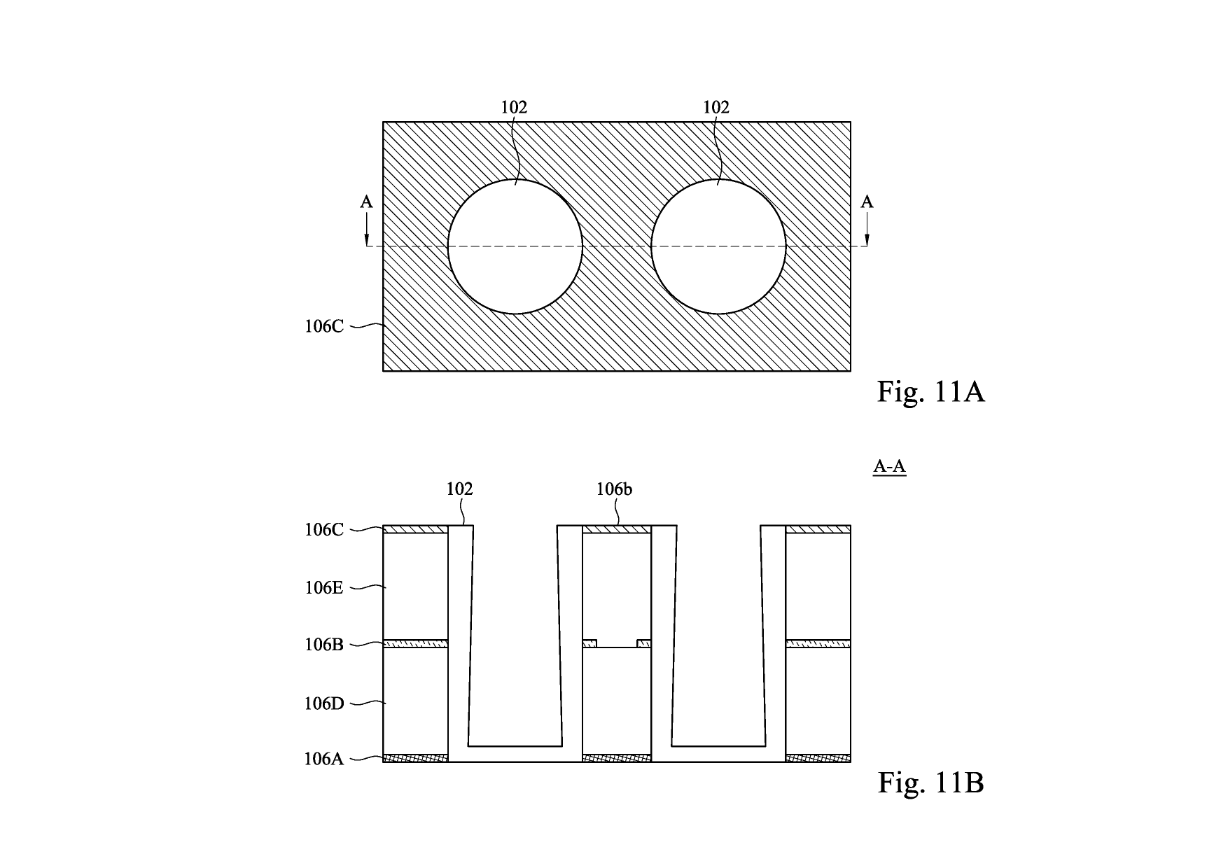

Refer to FIGS. 10A to 11B. The operation 208 includes removing the remaining portion 110b of the oxide layer 110 and the protecting layer 109 in the trench T1 to expose the bottom electrode 102. In some embodiments, removing the remaining portion 110b of the oxide layer 110 and the protecting layer 109 in the trench T1 is performed by any suitable etching method, for example, a wet etching method. In some embodiments, the wet etching method includes using a hydrofluoric acid solution as an etchant. In some embodiments, a volume ratio of HF to H₂O in the hydrofluoric acid solution is preferable from 1:200 to 1:400, for example, 1:200, 1:300, or 1:400.

Refer to FIGS. 11A to 11B, 14A to 14B, and 1A to 1C. The operation 209 includes forming the first dielectric layer 103I on the bottom electrode 102, and the operation 210 includes forming the first top electrode 104I on the first dielectric layer 103I. In some embodiments, the first dielectric layer 103I is conformally formed on the bottom electrode 102, and the first top electrode 104I is conformally formed on the first dielectric layer 103I. In some embodiments, forming the first dielectric layer 103I and the first top electrode 104I are respectively performed by any suitable deposition method, for example, an atomic layer deposition method. In the embodiments including the first filling layer 105I, the method 200 further includes forming the first filling layer 105I on the first top electrode 104I, as shown in FIG. 1A. In the embodiments including the first filling layer 105I, forming the first filling layer 105I is performed by any suitable deposition method, for example, a chemical vapor deposition method or a physical vapor deposition method.

In the embodiments including the second dielectric layer 103O and the second top electrode 104O, the method 200 further includes the following operations. Refer to FIGS. 11A to 14B and 1A to 1C. After performing the operation 208 to expose the bottom electrode 102, the portion 106b of the substrate 106 outside the trench T1 (or on the side OS of the bottom electrode 102) is removed. In some embodiments, the portion 106b of the substrate 106 includes portions of the top supporting layer 106C, the oxide layer 106D, and the oxide layer 106E, as described above, in order to expose the side OS of the bottom electrode 102 for forming the second dielectric layer 103O and the second top electrode 104O thereon. In some embodiments, the portion of the top supporting layer 106C is removed to form an opening O3 exposing the oxide layer 106E by a suitable etching process (e.g., a dry etching method), and the oxide layer 106E and the oxide layer 106D are removed through the opening O3 and the opening O1 by a suitable single etching process (e.g., a wet etching method) together, in which the opening O1 is formed in the previous operation, as described above. After removing the portion 106b of the substrate 106, the bottom supporting layer 106A, the middle supporting layer 106B, the top supporting layer 106C, and the bottom electrode 102 are exposed, in which the bottom supporting layer 106A, the middle supporting layer 106B, and the top supporting layer 106C provide the structural support to the bottom electrode 102, and the second dielectric layer 103O is formed on the side OS of the bottom electrode 102 opposite to the side IS of the bottom electrode 102 on which the first dielectric layer 103I is formed. In some embodiments, the second dielectric layer 103O is conformally formed on the bottom electrode 102 by any suitable deposition method, for example, an atomic layer deposition method. In some embodiments, forming the first dielectric layer 103I may be performed together with forming the second dielectric layer 103O in the same process, such that the first dielectric layer 103I having the same material as the second dielectric layer 103O is formed as the same layer as the second dielectric layer 103O, except that the first dielectric layer 103I and the second dielectric layer 103O are disposed on different sides of the bottom electrode 102. After forming the second dielectric layer 103O, the second top electrode 104O is formed on the second dielectric layer 103O. In some embodiments, the second top electrode 104O is conformally formed on the second dielectric layer 103O by any suitable deposition method, for example, an atomic layer deposition method. In some embodiments, forming the first top electrode 104I may be performed together with forming the second top electrode 104O in the same process, such that the first top electrode 104I having the same material as the second top electrode 104O is formed as the same layer as the second top electrode 104O, except that the first top electrode 104I and the second top electrode 104O are disposed on different sides of the bottom electrode 102. In the embodiments including the second filling layer 105O, after forming the second top electrode 104O, the method 200 further includes forming the second filling layer 105O on the second top electrode 104O, as shown in FIG. 1A. In the embodiments including the second filling layer 105O, forming the second filling layer 105O is performed by any suitable deposition method, for example, a chemical vapor deposition method or a physical vapor deposition method. In the embodiments including the first filling layer 105I and the second filling layer 105O, forming the first filling layer 105I may be performed together with forming the second filling layer 105O in the same process, such that the first filling layer 105I having the same material as the second filling layer 105O is formed as the same layer as the second filling layer 105O, except that the first filling layer 105I and the second filling layer 105O are disposed on different sides of the bottom electrode 102.

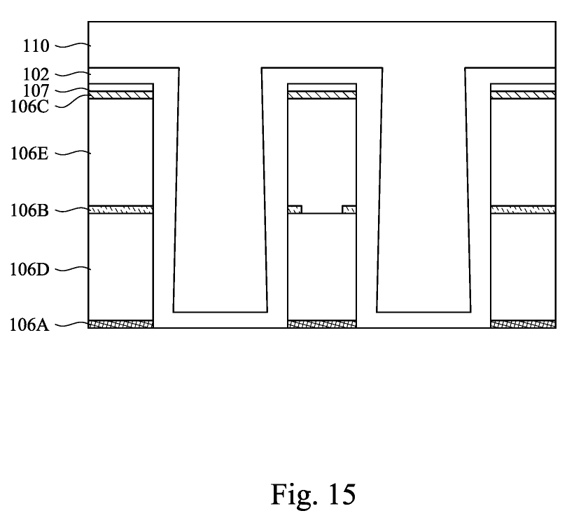

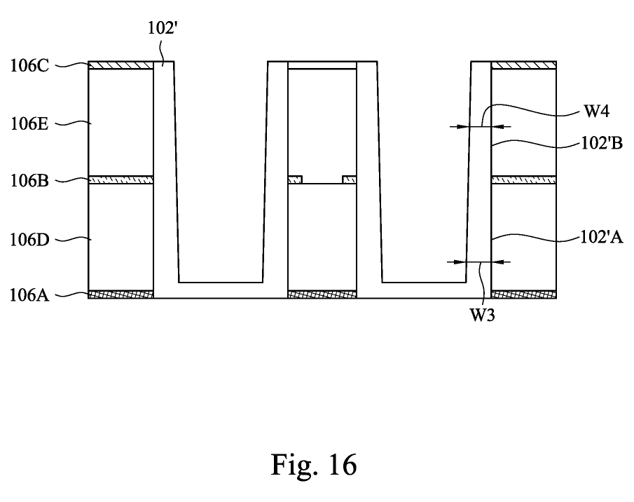

Next, refer to FIGS. 15 and 16. A comparative embodiment without forming the protecting layer 109 on the bottom electrode 102 is provided to form a comparative capacitor. In the comparative embodiment, the operations performed before forming the protecting layer 109 are substantially the same as the operations to form the capacitor 101 described above. Please refer to FIGS. 3A to 7B and the descriptions provided above. In the comparative embodiment, after forming the bottom electrode 102, the oxide layer 110 is formed on the bottom electrode 102 without forming the protecting layer 109 to separate the bottom electrode 102 from the oxide layer 110. During forming the oxide layer 110, the oxide layer 110 may deposit with higher energy on the top of the bottom electrode 102, and the energy decreases with the deposition performed to the bottom of the bottom electrode 102. Therefore, the top of the bottom electrode 102 may be oxidized easily compared with the bottom of the bottom electrode 102 by higher energy. After performing the operation similar to the operation 208 described above to expose the bottom electrode in the comparative embodiment, the width of the bottom electrode 102’ shown in FIG. 16 is reduced since the oxidized portion of the bottom electrode is removed easily in the operation similar to the operation 208, and the width reduction in the second portion 102’B of the bottom electrode 102 is larger than the width reduction in the first portion 102’A of the bottom electrode 102, in which the second portion 102’B is disposed above the first portion 102’A. In other words, in the comparative embodiment, the first width W3 of the first portion 102’A is larger than the second width W4 of the second portion 102’B, and the width of the bottom electrode 102’ of the comparative capacitor is smaller than the width of the bottom electrode 102 of the capacitor 101 described above. When the bottom electrode in the comparative embodiment is oxidized and/or the width of the bottom electrode in the comparative embodiment is reduced, the bottom electrode of the comparative embodiment may bend easily to affect the performance of the comparative capacitor, as described above. The rest of the operations to form the comparative capacitor may substantially be the same as the operations to form the capacitor 101 after the operation 208. Please refer to FIGS. 11A to 14B and 1A to 1C and the descriptions provided above.

The capacitor structure of the present disclosure and the capacitor structure formed by the method of the present disclosure include the bottom electrode not bent easily to improve the performance of the capacitor. Moreover, since the bottom electrode is not bent easily, the bottom electrode is prevented from staying too close to another bottom electrode of another capacitor disposed nearby, thereby preventing the current in the capacitors from leaking to each other.

The present disclosure is described in considerable detail in some embodiments, but other embodiments may also be feasible, so the description of the embodiments in the present disclosure is not intended to limit the scope and spirit of the claims attached. For one skilled in the art, the present disclosure may be modified and changed without deviating from the scope and spirit of the present disclosure. Such modifications and changes are intended to be covered by the present disclosure when they belong to the scope and spirit of the attached claims.

What is claimed is:

1. A capacitor, comprising:
a bottom electrode comprising a bottom portion and a side portion, wherein the side portion extends upward from an edge of the bottom portion, the side portion comprises a first portion and a second portion on the first portion, and a first width of the first portion is smaller than a second width of the second portion;
a first dielectric layer on the bottom electrode; and
a first top electrode on the first dielectric layer.

2. The capacitor of claim 1, wherein the first portion and the second portion together surround the first dielectric layer and the first top electrode.

3. The capacitor of claim 1, wherein a ratio of the second width to the first width is larger than 1 and smaller than or equal to 1.4.

4. The capacitor of claim 1, wherein the side portion has a width tapering from top to bottom.

5. The capacitor of claim 1, wherein a minimum of the first width is from 2 nm to 6 nm.

6. The capacitor of claim 1, wherein a maximum of the second width is larger than 2 nm and smaller than or equal to 8.4 nm.

7. The capacitor of claim 1, further comprising a second dielectric layer surrounding the first portion and the second portion, and a second top electrode surrounding the second dielectric layer.

8. A method of forming a capacitor, comprising:
forming a hard mask layer on a substrate;
forming a patterned photoresist layer comprising an opening on the hard mask layer;
removing a portion of the hard mask layer and a portion of the substrate through the opening of the patterned photoresist layer to form a trench;
forming a bottom electrode in the trench;
forming a protecting layer on the bottom electrode;
forming an oxide layer filling the trench and on the protecting layer and a remaining portion of the hard mask layer;
removing a portion of the oxide layer outside the trench and the remaining portion of the hard mask layer;
removing a remaining portion of the oxide layer in the trench and the protecting layer to expose the bottom electrode;
forming a first dielectric layer on the bottom electrode; and
forming a first top electrode on the first dielectric layer.

9. The method of claim 8, wherein the protecting layer separates the bottom electrode from the oxide layer.

10. The method of claim 8, wherein the protecting layer comprises lanthanide oxide, titanium oxide, aluminum oxide, silicon oxide, zirconium oxide, hafnium oxide, tantalum oxide, yttrium oxide, scandium oxide, gallium oxide, niobium oxide, magnesium oxide, silicon nitride, silicon oxynitride, or combinations thereof.

11. The method of claim 8, wherein a thickness of the protecting layer is smaller than or equal to 10 nm.

12. The method of claim 8, wherein forming the protecting layer is performed by a thermal atomic layer deposition method at a temperature smaller than or equal to 400 °C.

13. The method of claim 8, wherein the bottom electrode comprises a side portion on a sidewall surface of the trench, the side portion includes a first portion and a second portion on the first portion, and a first width of the first portion is smaller than a second width of the second portion.

14. The method of claim 8, wherein removing the portion of the oxide layer outside the trench and the remaining portion of the hard mask layer is performed by a chemical mechanical polishing method.

15. The method of claim 8, further comprising:
removing a portion of the substrate outside the trench after removing the remaining portion of the oxide layer and the protecting layer;
forming a second dielectric layer on a side of the bottom electrode opposite to a side of the bottom electrode on which the first dielectric layer is formed; and
forming a second top electrode on the second dielectric layer.
